(19) United States
(12) Patent Application Publication
(10) Pub. No.: US 2026/0150623 A1
(43) Pub. Date: May 28, 2026

(54) COLLET APPARATUS

(71) Applicant: Samsung Electronics Co., Ltd., Suwon-si (KR)

(72) Inventors: Ung-Keol KIM, Suwon-si (KR); Hee Sung PARK, Suwon-si (KR); Ho Jae KIM, Suwon-si (KR); Jung Ho PARK, Suwon-si (KR)

(73) Assignee: Samsung Electronics Co., Ltd., Suwon-si (KR)

(21) Appl. No.: 19/177,831

(22) Filed: Apr. 14, 2025

(30) Foreign Application Priority Data
Aug. 23, 2024 (KR) 10-2024-0113506

(51) Int. Cl. H10P 72/78; H10P 72/00; H10P 72/30

(52) U.S. Cl. CPC H10P 72/78; H10P 72/0446; H10P 72/3212

(57) ABSTRACT

A collet apparatus includes a body unit and an adsorption unit connected to a lower part of the body unit. The adsorption unit is configured to adsorb a semiconductor chip. The adsorption unit includes a first region, a second region, and a third region, the second region surrounds the first region, the third region surrounds the second region, the first region includes a plurality of first suction holes, the second region includes a plurality of second suction holes, the third region includes a plurality of third suction holes, a size of each of the plurality of second suction holes is smaller than a size of each of the plurality of first suction holes, and a size of each of the plurality of third suction holes is smaller than the size of each of the plurality of second suction holes.

### CROSS-REFERENCE TO RELATED APPLICATION

This U.S. non-provisional application claims priority under 35 U.S.C. § 119 to Korean Patent Application No. 10-2024-0113506 filed on Aug. 23, 2024, in the Korean Intellectual Property Office, and the entire contents of which are herein incorporated by reference.

### BACKGROUND

Example embodiments relate to a collet apparatus.

In a die bonding process, a die bonder may be used to bond individual dies, separated through a sawing process, onto a substrate such as a printed circuit board or lead frame by picking up the dies from the wafer and bonding them onto the substrate. The die bonder may include a collet for picking up the dies using vacuum and a bonding head coupled with the collet.

A collet that matches the size of semiconductor chips is used and the collet may be replaced when the size of semiconductor chip changes.

### SUMMARY

Some example embodiments are directed to a collet apparatus with improved compatibility.

Some example embodiments are directed to a collet apparatus having improved durability.

However, example embodiments are not restricted to those set forth herein. The above and other aspects of the present disclosure will become more apparent to one of ordinary skill in the art to which the present disclosure pertains by referencing the detailed description of the present disclosure given below.

According to some example embodiments, a collet apparatus includes a body unit and an adsorption unit connected to a lower part of the body unit. The adsorption unit is configured to adsorb a semiconductor chip. The adsorption unit includes a first region, a second region, and a third region, the second region surrounds the first region, the third region surrounds the second region, the first region includes a plurality of first suction holes, the second region includes a plurality of second suction holes, the third region includes a plurality of third suction holes, a size of each of the plurality of second suction holes is smaller than a size of each of the plurality of first suction holes, and a size of each of the plurality of third suction holes is smaller than the size of each of the plurality of second suction holes.

According to some example embodiments, a collet apparatus includes a body unit and an adsorption unit connected to a lower part of the body unit. The adsorption unit is configured to adsorb a semiconductor chip. The adsorption unit includes a first region and a second region, the second region surrounds the first region, the first region includes a plurality of first suction holes, the second region includes a plurality of second suction holes, and a size of each of the plurality of second suction holes is smaller than a size of each of the plurality of first suction holes.

According to some example embodiments, a collet apparatus includes a body unit, an adsorption unit connected to a lower part of the body unit, the adsorption unit being configured to adsorb a semiconductor chip, and a suction line configured to adsorb the semiconductor chip to the adsorption unit. The adsorption unit includes a first region, a second region, and a third region, the second region surrounds the first region, the third region surrounds the second region, the first region includes a plurality of first suction holes, the second region includes a plurality of second suction holes, the third region includes a plurality of third suction holes, a size of each of the plurality of second suction holes is smaller than a size of each of the plurality of first suction holes, a size of each of the plurality of third suction holes is smaller than the size of each of the plurality of second suction holes, an area of the plurality of first suction holes is at least 60% of a sum of areas of the plurality of first suction holes, the plurality of second suction holes, and the plurality of third suction holes, an area of the first region is less than 30% of a total area of the adsorption unit, and the suction line is connected to the plurality of first suction holes, the plurality of second suction holes, and the plurality of third suction holes.

While example embodiments have been provided in the present disclosure, it should be understood that the disclosed example embodiments might be embodied in many other forms without departing from the spirit or scope of the present disclosure.

### BRIEF DESCRIPTION OF THE DRAWINGS

The above and other aspects and features of the example embodiments will more clearly understood from the following detailed description taken in conjunction with the accompanying drawings.

FIG. 1 is a perspective view of a collet apparatus, according to some example embodiments.

FIG. 2 is a bottom view illustrating an adsorption unit of the collet apparatus, according to some example embodiments.

FIGS. 3, 4, and 5 are cross-sectional views taken along line I-I′ of FIG. 2.

FIGS. 6, 7, 8, 9, 10, 11, and 12 illustrate adsorption units of collet apparatuses, according to some example embodiments.

### DETAILED DESCRIPTION

Example embodiments will hereinafter be described in detail with reference to the accompanying drawings. The same reference numerals are used for the same components in the drawings, and thus, redundant descriptions thereof will be omitted.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%

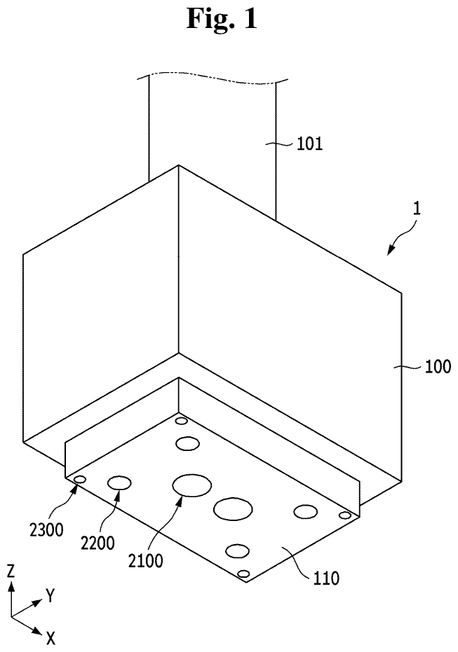

FIG. 1 is a perspective view illustrating a collet apparatus, according to some example embodiments.

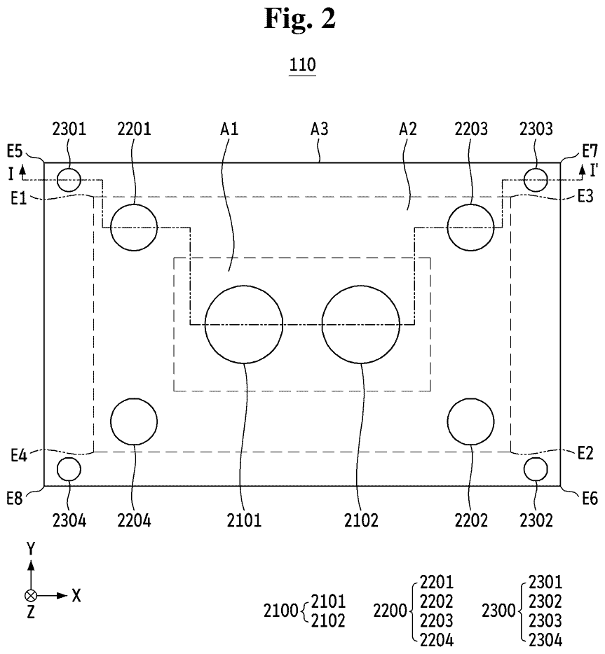

FIG. 2 is a bottom view illustrating an adsorption unit of the collet apparatus, according to some example embodiments of the present disclosure.

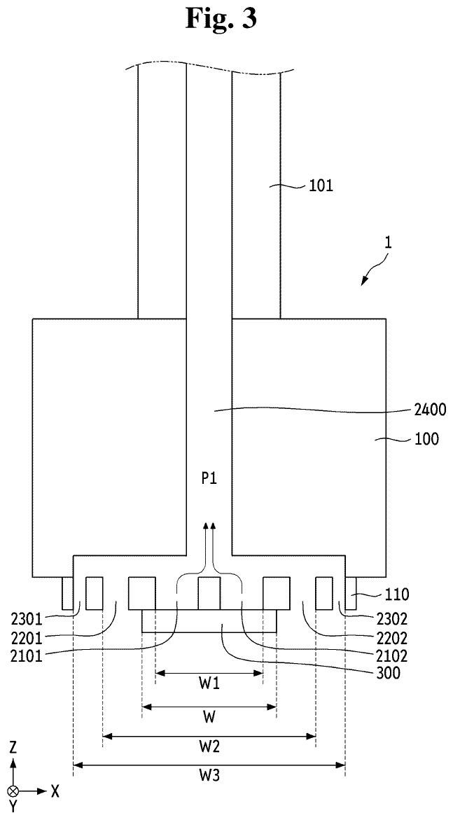

FIGS. 3 through 5 are cross-sectional views taken along line I-I′ of FIG. 2.

Referring to FIGS. 1 through 3, a collet apparatus 1 includes a body unit 100, a connection unit 101, an adsorption unit 110, and a suction line 2400.

The connection unit 101 may be connected to the body unit 100. The collet apparatus 1 may be connected to an external device through the connection unit 101.

The adsorption unit 110 may be connected to the lower part of the body unit 100. The width of the adsorption unit 110 in a first direction X may be smaller than the width of the body unit 100 in the first direction X. Additionally, the width of the adsorption unit 110 in a second direction Y, which is perpendicular to the first direction X, may be smaller than the width of the body unit 100 in the second direction Y.

The adsorption unit 110 may include a first region A1, a second region A2, and a third region A3. The first region A1 may be disposed at or about the center of the adsorption unit 110. The second region A2 may be disposed about the first region A1 and may surround the first region A1 along the outer edge of the first region A1. The third region A3 may be disposed about the second region A2 and may surround the second region A2 along the outer edge of the second region A2. The third region A3 may be or include (or otherwise coincide with) the peripheral edges of the adsorption unit 110.

In some example embodiments, the first region A1 may include a plurality of first suction holes 2100. The first suction holes 2100 may be arranged along the first direction X. For example, the first suction holes 2100 may include a first sub-suction hole 2101 and a second sub-suction hole 2102. The first suction holes 2100 are illustrated as including two sub-suction holes, but example embodiments not limited thereto. Alternatively, in some example embodiments, the first suction holes 2100 may include three or more sub-suction holes.

In some example embodiments, the second region A2 may be generally rectangular region and the second region A2 may include a plurality of second suction holes 2200. The second suction holes 2200 may be arranged along the corners of the second region A2. For example, the second region A2 may include a first corner E1 and a second corner E2 diagonally opposite to each other, and a third corner E3 and a fourth corner E4 diagonally opposite to each other. The first corner E1 and the third corner E3 may be opposite each other in the X direction. The second corner E2 and the fourth corner E4 may be opposite each other in the X direction. The first corner E1 and the fourth corner E4 may be opposite each other in the Y direction. The third corner E3 and the second corner E2 may be opposite each other in the Y direction. A third sub-suction hole 2201 may be disposed at or adjacent the first corner E1. A fourth sub-suction hole 2202 may be disposed at or adjacent the second corner E2. The fifth sub-suction hole 2203 may be disposed at or adjacent the third corner E3. The sixth sub-suction hole 2204 may be disposed at or adjacent the fourth corner E4. With the second suction holes 2200 disposed at the corners of the second region A2, a semiconductor chip 300 may be securely adsorbed (or picked up using vacuum or suction).

In some example embodiments, the third region A3 may include a plurality of third suction holes 2300. The third suction holes 2300 may be arranged along the corners of the third region A3. For example, the third region A3 may include a fifth corner E5 and a sixth corner E6 diagonally opposite to each other, and a seventh corner E7 and an eighth corner E8 diagonally opposite to each other. The fifth corner E5 and the seventh corner E7 may be opposite each other in the X direction. The eighth corner E8 and the sixth corner E6 may be opposite each other in the X direction. The fifth corner E5 and the eighth corner E8 may be opposite each other in the Y direction. The seventh corner E7 and the sixth corner E6 may be opposite each other in the Y direction. The seventh sub-suction hole 2301 may be disposed at or adjacent the fifth corner E5. The eighth sub-suction hole 2302 may be disposed at or adjacent the sixth corner E6. A ninth sub-suction hole 2303 may be disposed at or adjacent the seventh corner E7. A tenth sub-suction hole 2304 may be disposed at or adjacent the eighth corner E8. With the third suction holes 2300 disposed at the corners of the third region A3, the semiconductor chip 300 can be securely adsorbed (or picked up using vacuum or suction).

In some example embodiments, the size of the first suction holes 2100 may be larger than the size of the second suction holes 2200, and the size of the second suction holes 2200 may be larger than the size of the third suction holes 2300. The area of the first suction holes 2100 may be between 60% (or about 60%) and 80% (or about 80%) of the sum of the areas of the first suction holes 2100, the second suction holes 2200, and the third suction holes 2300 included in the adsorption unit 110. In some example embodiments, the area of the first suction holes 2100 may be 60% (or about 60%) of the sum of the areas of the first suction holes 2100, the second suction holes 2200, and the third suction holes 2300. The sum of the areas of the first suction holes 2100 and the second suction holes 2200 may be between 60% (or about 60%) and 95% (or about 95%) of the sum of the areas of the first suction holes 2100, the second suction holes 2200, and the third suction holes 2300 included in the adsorption unit 110. In some example embodiments, the sum of the areas of the first suction holes 2100 and the second suction holes 2200 may be 85% (or about 85%) of the sum of the areas of the first suction holes 2100, the second suction holes 2200, and the third suction holes 2300.

In some example embodiments, the area of the first region A1 may be less than 30% (or about 30%) of the total area of the adsorption unit 110. Further, the sum of the areas of the first and second regions A1 and A2 may be less than 60% (or about 60%) of the total area of the adsorption unit 110.

By adjusting the area of the suction holes (2100, 2200, and 2300) and the area of the regions (A1, A2, and A3) in which the suction holes (2100, 2200, and 2300) are disposed, an appropriate (or desired) pressure for adsorbing the semiconductor chip 300 can be generated in each of the regions (A1, A2, and A3). Through this, a single collet apparatus 1 may adsorb semiconductor chips 300 of different (or varied) sizes. As a result, the collet apparatus 1 may have improved compatibility.

A semiconductor chip 300 may be adsorbed onto the lower surface of the adsorption unit 110. The semiconductor chip 300 may be, for example, any one of a logic semiconductor chip, a memory semiconductor chip, a semiconductor package, or an interposer.

The logic semiconductor chip may be, for example, a central processing unit (CPU), a controller, or an application-specific integrated circuit (ASIC).

The memory semiconductor chip may be, for example, a volatile memory semiconductor chip, such as a dynamic random-access memory (DRAM) or static random-access memory (SRAM), or a non-volatile memory semiconductor chip, such as phase-change random-access memory (PRAM), magnetoresistive random-access memory (MRAM), ferroelectric random-access memory (FeRAM), or resistive random-access memory (RRAM). However, example embodiments are not limited thereto.

The adsorption unit 110 may include a material with relatively higher resistance and/or higher hardness properties. For example, the adsorption unit 110 may include ceramic, but example embodiments are not limited thereto. Alternatively, in some example embodiments, the adsorption unit 110 may include a material having higher resistance and/or higher hardness properties than ceramic. The collet apparatus 1 may have improved durability.

The suction line 2400 may be disposed to pass through the connection unit 101 and the body unit 100. The suction line 2400 may intake air, thereby create a vacuum environment (or a pressure differential) on or adjacent the lower surface of the adsorption unit 110, adsorb the semiconductor chip 300 onto the lower surface of the adsorption unit 110.

The suction line 2400 may be disposed to pass through the connection unit 101 and the body unit 100 in a third direction Z. The suction line 2400 may be fluidly connected to the first suction holes 2100, the second suction holes 2200, and the third suction holes 2300.

Air may be drawn in through the first suction holes 2100, the second suction holes 2200, the third suction holes 2300, and the suction line 2400. Using the drawn-in air, the semiconductor chip 300 may be adsorbed onto the lower surface of the adsorption unit 110.

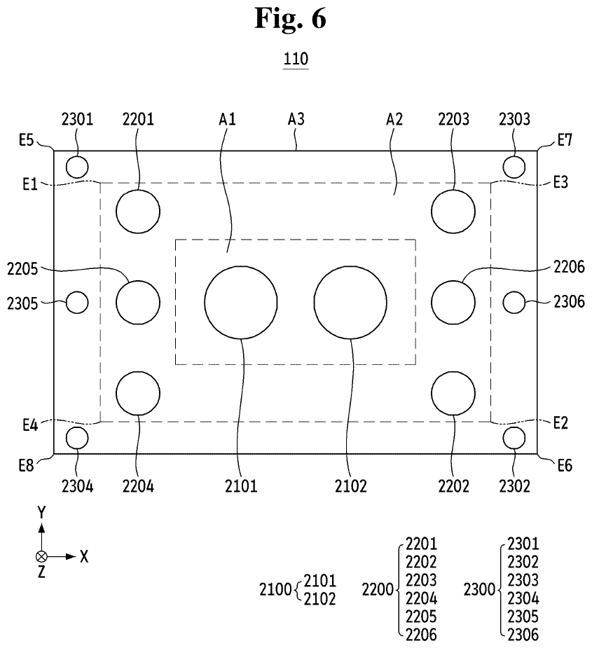

The collet apparatus 1 in FIG. 1 is illustrated as including the adsorption unit 110 illustrated in FIG. 2, but example embodiments are not limited thereto. Alternatively, in some example embodiments, the collet apparatus 1 may include adsorption units 110 illustrated in FIGS. 6 through 12.

Referring to FIG. 3, the distance between the first suction holes 2100 disposed farthest apart in the first direction X may be a first width W1. In this disclosure, the distance between suction holes refers to the distance between the two points in the suction holes that are farthest apart in the first direction X. Similarly, the distance between the second suction holes 2200 may be a second width W2, and the distance between the third suction holes 2300 may be a third width W3.

In some example embodiments, the width of the semiconductor chip 300 may be a fourth width W. The fourth width W may be greater than the first width W1 and smaller than the second width W2. Therefore, the semiconductor chip 300 can be adsorbed onto the adsorption unit 110 by the first suction holes 2100. The pressure applied by the first suction holes 2100 may be a first pressure P1. For example, the first pressure P1 may be between −50 KPA (or about −50 KPA) and −60 KPA (or about −60 KPA), but example embodiments are not limited thereto.

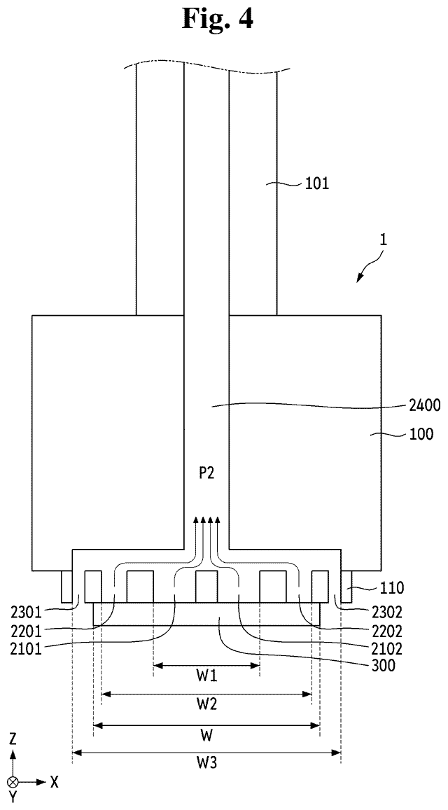

Referring to FIG. 4, the distance between the first suction holes 2100 disposed farthest apart in the first direction X may be a first width W1, the distance between the second suction holes 2200 may be a second width W2, and the distance between the third suction holes 2300 may be a third width W3.

In some example embodiments, the width of the semiconductor chip 300 may be a fourth width W. The fourth width W may be greater than the second width W2 and smaller than the third width W3. Therefore, the semiconductor chip 300 may be adsorbed onto the adsorption unit 110 by the first suction holes 2100 and the second suction holes 2200. The pressure applied by the first suction holes 2100 and the second suction holes 2200 may be a second pressure P2. For example, the second pressure P2 may be between −65 KPA (or about −65 KPA) and −80 KPA (or about −80 KPA), but example embodiments are not limited thereto.

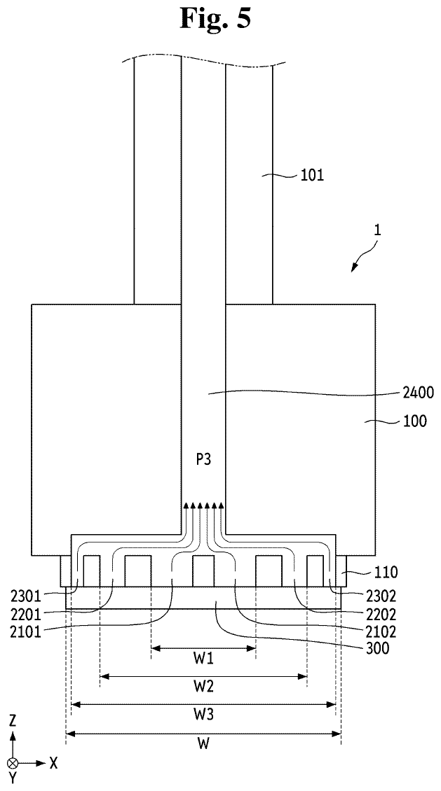

Referring to FIG. 5, the distance between the first suction holes 2100 positioned farthest apart in the first direction X may be a first width W1, the distance between the second suction holes 2200 may be a second width W2, and the distance between the third suction holes 2300 may be a third width W3.

In some example embodiments, the width of the semiconductor chip 300 may be a fourth width W. The fourth width W may be greater than the third width W3. Therefore, the semiconductor chip 300 may be adsorbed onto the adsorption unit 110 by the first suction holes 2100, the second suction holes 2200, and the third suction holes 2300. The pressure applied by the first suction holes 2100, the second suction holes 2200, and the third suction holes 2300 may be a third pressure P3. For example, the third pressure P3 may be between −70 KPA (or about −70 KPA) and −90 KPA (or about −90 KPA), but example embodiments are not limited thereto.

As illustrated in FIGS. 3 through 5, the collet apparatus 1 may adsorb semiconductor chips 300 of different (or varied) sizes. The collet apparatus 1 may thus have improved compatibility.

FIGS. 6 through 12 illustrate bottom views of adsorption units of collet apparatuses, according to some example embodiments. The adsorption units 110 in FIG. 6-12 may be same as or similar in some respects to the adsorption units 110 of FIGS. 1-2, and therefore may be best understood with reference thereto where like numerals indicate like elements. Some example embodiments discussed below include a sub-section hole being between two sub-section holes. Such a sub-section hole may be mid-way between the two sub-section holes or may be closer to one of the two sub-section holes than the other of the two sub-section holes.

Referring to FIG. 6, an adsorption unit 110 may include a first region A1, a second region A2, and a third region A3. The first region A1 may be disposed at or about the center of the adsorption unit 110. The second region A2 may be disposed about the first region A1 and may surround the first region A1 along the outer edge of the first region A1. The third region A3 may be disposed about the second region A2 and may surround the second region A2 along the outer edge of the second region A2. The third region A3 may be or include (or otherwise coincide with) the peripheral edges of the adsorption unit 110.

In some example embodiments, the first region A1 may include a plurality of first suction holes 2100. The first suction holes 2100 may be arranged along a first direction X. For example, the first suction holes 2100 may include a first sub-suction hole 2101 and a second sub-suction hole 2102. The first suction holes 2100 are illustrated as including two sub-suction holes, but example embodiments are not limited thereto. In some example embodiments, the first suction holes 2100 may include three or more sub-suction holes.

In some example embodiments, the second region A2 may include a plurality of second suction holes 2200. The second suction holes 2200 may be arranged at or along the corners of the second region A2. For example, the second region A2 may include a first corner E1 and a second corner E2 diagonally opposite to each other, and a third corner E3 and a fourth corner E4 diagonally opposite to each other. The third sub-suction hole 2201 may be disposed at the first corner E1. The fourth sub-suction hole 2202 may be disposed at the second corner E2. The fifth sub-suction hole 2203 may be disposed at the third corner E3. The sixth sub-suction hole 2204 may be disposed at the fourth corner E4.

The third region A3 may include a plurality of third suction holes 2300. The third suction holes 2300 may be arranged at or along the corners of the third region A3. For example, the third region A3 may include a fifth corner E5 and a sixth corner E6 diagonally opposite to each other, and a seventh corner E7 and an eighth corner E8 diagonally opposite to each other. The seventh sub-suction hole 2301 may be disposed at the fifth corner E5. The eighth sub-suction hole 2302 may be disposed at the sixth corner E6. The ninth sub-suction hole 2303 may be disposed at the seventh corner E7. The tenth sub-suction hole 2304 may be disposed at the eighth corner E8.

Additionally, the second suction holes 2200 may further include an eleventh sub-suction hole 2205 between the third and sixth sub-suction holes 2201 and 2204, and a twelfth sub-suction hole 2206 between the fourth and fifth sub-suction holes 2202 and 2203. The third suction holes 2300 may further include a thirteenth sub-suction hole 2305 between the seventh and tenth sub-suction holes 2301 and 2304, and a fourteenth sub-suction hole 2306 between the eighth and ninth sub-suction holes 2302 and 2303.

By disposing the second suction holes 2200 and the third suction holes 2300 along the corners and both sides of the second region A2 and the third region A3, respectively, a semiconductor chip 300 can be securely adsorbed.

In some example embodiments, the size of the first suction holes 2100 may be larger than the size of the second suction holes 2200, and the size of the second suction holes 2200 may be larger than the size of the third suction holes 2300. The area of the first suction holes 2100 may be between 60% (or about 60%) and 80% (or about 80%) of the sum of the areas of the first suction holes 2100, the second suction holes 2200, and the third suction holes 2300 included in the adsorption unit 110. In some example embodiments, the area of the first suction holes 2100 may be 60% (or about 60%) of the sum of the areas of the suction holes (2100, 2200, and 2300). The sum of the areas of the first suction holes 2100 and the second suction holes 2200 may be between 60% (or about 60%) and 95% (or about 95%) of the sum of the areas of the suction holes (2100, 2200, and 2300) included in the adsorption unit 110. In some example embodiments, the sum of the areas of the first suction holes 2100 and the second suction holes 2200 may be 85% (or about 85%) of the total area of the suction holes (2100, 2200, and 2300).

The area of the first region A1 may be less than 30% (or about 30%) of the sum of the areas of the first, second, and third regions A1, A2, and A3 of the adsorption unit 110. The sum of the areas of the first and second regions A1 and A2 may be less than 60% (or about 60%) of the total area of the adsorption unit 110.

By adjusting the area of the suction holes (2100, 2200, and 2300) and the area of the regions (A1, A2, and A3) where the suction holes (2100, 2200, and 2300) are disposed, an appropriate (or desired) pressure for adsorbing the semiconductor chip 300 can be generated in each of the regions (A1, A2, and A3). Through this, a single collet apparatus 1 may adsorb semiconductor chips 300 of different (or varied) sizes. The collet apparatus 1 may thus have improved compatibility.

The adsorption unit 110 may include a material with relatively higher resistance and/or higher hardness properties. For example, the adsorption unit 110 may include ceramic, but example embodiments are limited thereto. Alternatively, in some example embodiments, the adsorption unit 110 may include a material having higher resistance and/or higher hardness properties than ceramic. The collet apparatus 1 may therefore have improved durability.

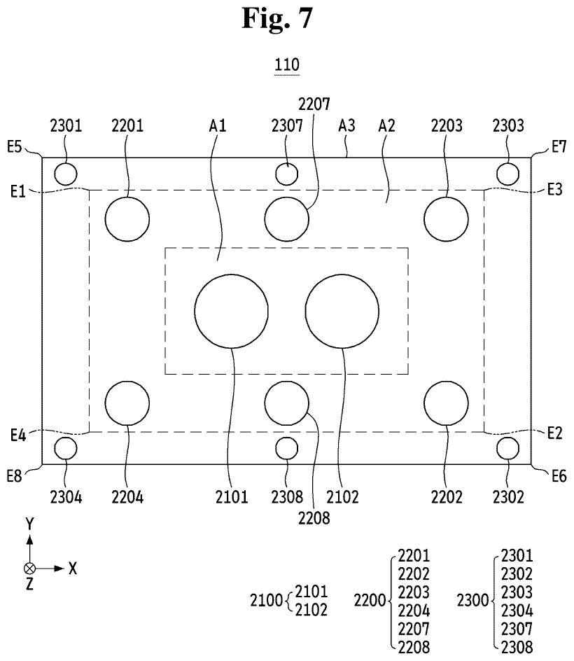

Referring to FIG. 7, an adsorption unit 110 may include a first region A1, a second region A2, and a third region A3. The first region A1 may be disposed at or about the center of the adsorption unit 110. The second region A2 may be disposed about the first region A1 and may surround the first region A1 along the outer edge of the first region A1. The third region A3 may be disposed about the second region A2 and may surround the second region A2 along the outer edge of the second region A2. The third region A3 may be or include (or otherwise coincide with) the peripheral edges of the adsorption unit 110.

In some example embodiments, the first region A1 may include a plurality of first suction holes 2100. The first suction holes 2100 may be arranged along a first direction X. For example, the first suction holes 2100 may include a first sub-suction hole 2101 and a second sub-suction hole 2102. The first suction holes 2100 are illustrated as including two sub-suction holes, but example embodiments are not limited thereto. In some example embodiments, the first suction holes 2100 may include three or more sub-suction holes.

In some example embodiments, the second region A2 may include a plurality of second suction holes 2200. The second suction holes 2200 may be arranged along the corners of the second region A2. For example, the second region A2 may include a first corner E1 and a second corner E2 diagonally opposite to each other, and a third corner E3 and a fourth corner E4 diagonally opposite to each other. The third sub-suction hole 2201 may be disposed at the first corner E1. The fourth sub-suction hole 2202 may be disposed at the second corner E2. The fifth sub-suction hole 2203 may be disposed at the third corner E3. The sixth sub-suction hole 2204 may be disposed at the fourth corner E4.

The third region A3 may include a plurality of third suction holes 2300. The third suction holes 2300 may be arranged at or along the corners of the third region A3. For example, the third region A3 may include a fifth corner E5 and a sixth corner E6 diagonally opposite to each other, and a seventh corner E7 and an eighth corner E8 diagonally opposite to each other. The seventh sub-suction hole 2301 may be disposed at the fifth corner E5. The eighth sub-suction hole 2302 may be disposed at the sixth corner E6. The ninth sub-suction hole 2303 may be disposed at the seventh corner E7. The tenth sub-suction hole 2304 may be disposed at the eighth corner E8.

Additionally, the second suction holes 2200 may further include a fifteenth sub-suction hole 2207 between the third and fifth sub-suction holes 2201 and 2203, and a sixteenth sub-suction hole 2208 between the fourth and sixth sub-suction holes 2202 and 2204. The third suction holes 2300 may further include a seventeenth sub-suction hole 2307 between the seventh and ninth sub-suction holes 2301 and 2303, and an eighteenth sub-suction hole 2308 between the eighth and tenth sub-suction holes 2302 and 2304.

By disposing the second suction holes 2200 and the third suction holes 2300 along the corners and both sides of the second region A2 and the third region A3, respectively, a semiconductor chip 300 can be securely adsorbed.

In some example embodiments, the size of the first suction holes 2100 may be larger than the size of the second suction holes 2200, and the size of the second suction holes 2200 may be larger than the size of the third suction holes 2300. The area of the first suction holes 2100 may be between 60% (or about 60%) and 80% (or about 80%) of the sum of the areas of the first suction holes 2100, the second suction holes 2200, and the third suction holes 2300 included in the adsorption unit 110. In some example embodiments, the area of the first suction holes 2100 may be 60% (or about 60%) of the sum of the areas of the suction holes (2100, 2200, and 2300). The sum of the areas of the first suction holes 2100 and the second suction holes 2200 may be between 60% (or about 60%) and 95% (or about 95%) of the sum of the areas of the suction holes (2100, 2200, and 2300) included in the adsorption unit 110. In some example embodiments, the sum of the areas of the first suction holes 2100 and the second suction holes 2200 may be 85% (or about 85%) of the total area of the suction holes (2100, 2200, and 2300).

Additionally, the area of the first region A1 may be less than 30% (or about 30%) of the total area of the adsorption unit 110. Furthermore, the sum of the areas of the first and second regions A1 and A2 may be less than 60% (or about 60%) of the total area of the adsorption unit 110.

By adjusting the area of the suction holes (2100, 2200, and 2300) and the area of the regions (A1, A2, and A3) where the suction holes (2100, 2200, and 2300) are disposed, an appropriate (or desired) pressure for adsorbing the semiconductor chip 300 can be generated in each of the regions (A1, A2, and A3). As a result, a single collet apparatus 1 may adsorb semiconductor chips 300 of different (or varied) sizes. The collet apparatus 1 may have improved compatibility.

The adsorption unit 110 may include a material with relatively higher resistance and/or higher hardness properties. For example, the adsorption unit 110 may include ceramic, but example embodiments are not limited thereto. Alternatively, in some example embodiments, the adsorption unit 110 may include materials with relatively higher resistance and/or higher hardness properties than ceramic. As a result, the collet apparatus 1 may have improved durability.

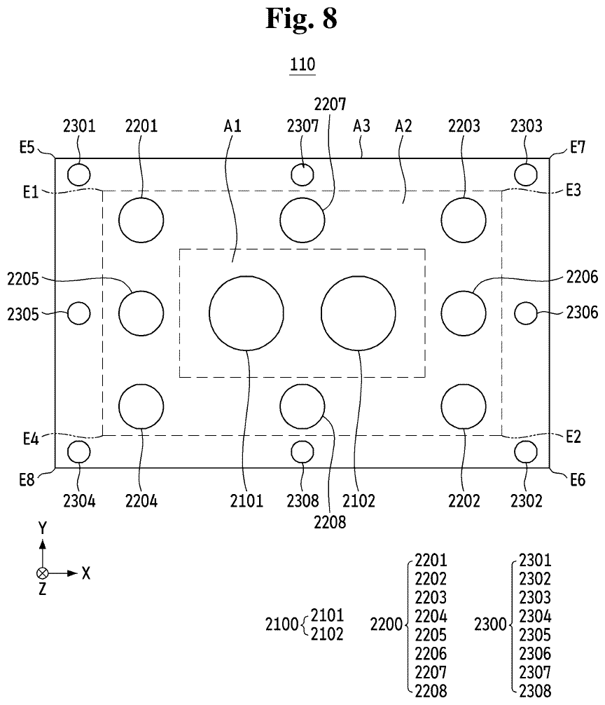

Referring to FIG. 8, an adsorption unit 110 may include a first region A1, a second region A2, and a third region A3. The first region A1 may be disposed at or about the center of the adsorption unit 110. The second region A2 may be disposed about the first region A2 and may surround the first region A1 along the outer edge of the first region A1. The third region A3 may be disposed about the second region A2 and may surround the second region A2 along the outer edge of the second region A2. The third region A3 may be or include (or otherwise coincide with) the peripheral edges of the adsorption unit 110.

In some example embodiments, the first region A1 may include a plurality of first suction holes 2100. The first suction holes 2100 may be arranged along a first direction X. For example, the first suction holes 2100 may include a first sub-suction hole 2101 and a second sub-suction hole 2102. The first suction holes 2100 are illustrated as including two sub-suction holes, but example embodiments are not limited thereto. In some example embodiments, the first suction holes 2100 may include three or more sub-suction holes.

In some example embodiments, the second region A2 may include a plurality of second suction holes 2200. The second suction holes 2200 may be arranged at or along the corners of the second region A2. For example, the second region A2 may include a first corner E1 and a second corner E2 diagonally opposite to each other, and a third corner E3 and a fourth corner E4 diagonally opposite to each other. The third sub-suction hole 2201 may be disposed at the first corner E1. The fourth sub-suction hole 2202 may be disposed at the second corner E2. The fifth sub-suction hole 2203 may be disposed at the third corner E3. The sixth sub-suction hole 2204 may be disposed at the fourth corner E4.

The third region A3 may include a plurality of third suction holes 2300. The third suction holes 2300 may be arranged along the corners of the third region A3. For example, the third region A3 may include a fifth corner E5 and a sixth corner E6 diagonally opposite to each other, and a seventh corner E7 and an eighth corner E8 diagonally opposite to each other. The seventh sub-suction hole 2301 may be disposed at the fifth corner E5. The eighth sub-suction hole 2302 may be disposed at the sixth corner E6. The ninth sub-suction hole 2303 may be disposed at the seventh corner E7. The tenth sub-suction hole 2304 may be disposed at the eighth corner E8.

Additionally, the second suction holes 2200 may further include the eleventh sub-suction hole 2205 between the third and sixth sub-suction holes 2201 and 2204, the twelfth sub-suction hole 2206 between the fourth and fifth sub-suction holes 2202 and 2203, the fifteenth sub-suction hole 2207 between the third and fifth sub-suction holes 2201 and 2203, and the sixteenth sub-suction hole 2208 between the fourth and sixth sub-suction holes 2202 and 2204. The third suction holes 2300 may further include the thirteenth sub-suction hole 2305 between the seventh and tenth sub-suction holes 2301 and 2304, the fourteenth sub-suction hole 2306 between the eighth and ninth sub-suction holes 2302 and 2303, the seventeenth sub-suction hole 2307 between the seventh and ninth sub-suction holes 2301 and 2303, and the eighteenth sub-suction hole 2308 between the eighth and tenth sub-suction holes 2302 and 2304.

By disposing the second suction holes 2200 and the third suction holes 2300 along the corners and the four sides of the second region A2 and the third region A3, respectively, a semiconductor chip 300 can be securely adsorbed.

In some example embodiments, the size of the first suction holes 2100 may be larger than the size of the second suction holes 2200, and the size of the second suction holes 2200 may be larger than the size of the third suction holes 2300. The area of the first suction holes 2100 may be between 60% (or about 60%) and 80% (or about 80%) of the sum of the areas of the first suction holes 2100, the second suction holes 2200, and the third suction holes 2300 included in the adsorption unit 110. In some example embodiments, the area of the first suction holes 2100 may be 60% (or about 60%) of the sum of the areas of the suction holes (2100, 2200, and 2300). The sum of the areas of the first suction holes 2100 and the second suction holes 2200 may be between 60% (or about 60%) and 95% (or about 95%) of the total area of the suction holes (2100, 2200, and 2300) included in the adsorption unit 110. In some example embodiments, the sum of the areas of the first suction holes 2100 and the second suction holes 2200 may be about 85% (or about 85%) of the total area of the suction holes (2100, 2200, and 2300).

Additionally, the area of the first region A1 may be less than 30% (or about 30%) of the total area of the adsorption unit 110. Furthermore, the sum of the areas of the first and second regions A1 and A2 may be less than 60% (or about 60%) of the total area of the adsorption unit 110.

By adjusting the area of the suction holes (2100, 2200, and 2300) and the area of the regions (A1, A2, and A3) where the suction holes (2100, 2200, and 2300) are disposed, an appropriate (or desired) pressure for adsorbing the semiconductor chip 300 may be generated in each of the regions (A1, A2, and A3). As a result, a single collet apparatus 1 may adsorb semiconductor chips 300 of different (or varied) sizes. The collet apparatus 1 may have improved compatibility.

The adsorption unit 110 may include a material having relatively higher resistance and/or higher hardness properties. For example, the adsorption unit 110 may include ceramic, but example embodiments are not limited thereto. Alternatively, in some example embodiments, the adsorption unit 110 may include a material having higher resistance and/or higher hardness properties than ceramic. The collet apparatus 1 may have improved durability.

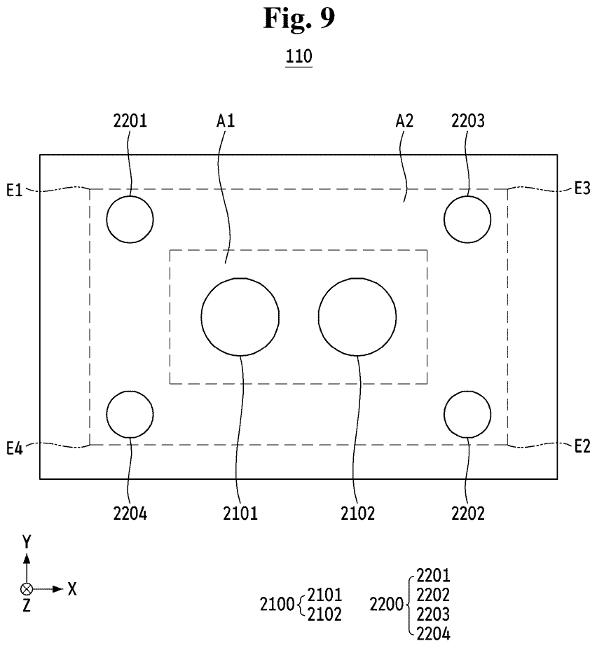

Referring to FIG. 9, an adsorption unit 110 may include a first region A1 and a second region A2. The first region A1 may be disposed at or about the center of the adsorption unit 110. The second region A2 may be disposed about the first region A1 and may surround the first region A1 along the outer edge of the first region A1.

In some example embodiments, the first region A1 may include a plurality of first suction holes 2100. The first suction holes 2100 may be arranged along a first direction X. For example, the first suction holes 2100 may include a first sub-suction hole 2101 and a second sub-suction hole 2102. The first suction holes 2100 are illustrated as including two sub-suction holes, but example embodiments are not limited thereto. Alternatively, in some example embodiments, the first suction holes 2100 may include three or more sub-suction holes.

In some example embodiments, the second region A2 may include a plurality of second suction holes 2200. The second suction holes 2200 may be arranged along the corners of the second region A2. For example, the second region A2 may include a first corner E1 and a second corner E2 diagonally opposite to each other, and a third corner E3 and a fourth corner E4 diagonally opposite to each other. The third sub-suction hole 2201 may be disposed at the first corner E1. The fourth sub-suction hole 2202 may be disposed at the second corner E2. The fifth sub-suction hole 2203 may be disposed at the third corner E3. The sixth sub-suction hole 2204 may be disposed at the fourth corner E4.

By disposing the second suction holes 2200 at the corners of the second region A2, the semiconductor chip 300 can be securely adsorbed.

In some example embodiments, the size of the first suction holes 2100 may be larger than the size of the second suction holes 2200. The area of the first suction holes 2100 may be between 60% (or about 60%) and 80% (or about 80%) of the sum of the areas of the first suction holes 2100 and the second suction holes 2200 included in the adsorption unit 110. In some example embodiments, the area of the first suction holes 2100 may be 60% (or about 60%) of the total area of the suction holes (2100 and 2200).

Additionally, the area of the first region A1 may be less than 30% (or about 30%) of the total area of the adsorption unit 110.

By adjusting the area of the suction holes (2100, 2200, and 2300) and the area of the regions (A1, A2, and A3) where the suction holes (2100, 2200, and 2300) are disposed, an appropriate (or desired) pressure for adsorbing the semiconductor chip 300 may be generated in each of the regions (A1, A2, and A3). As a result, a single collet apparatus 1 may adsorb semiconductor chips 300 of different (or varied) sizes. The collet apparatus 1 having improved compatibility.

The adsorption unit 110 may include a material with relatively higher resistance and/or higher hardness properties. For example, the adsorption unit 110 may include ceramic, but example embodiments are not limited thereto. Alternatively, in some example embodiments, the adsorption unit 110 may include a material having a higher resistance and/or higher hardness than ceramic. The collet apparatus 1 may have improved durability.

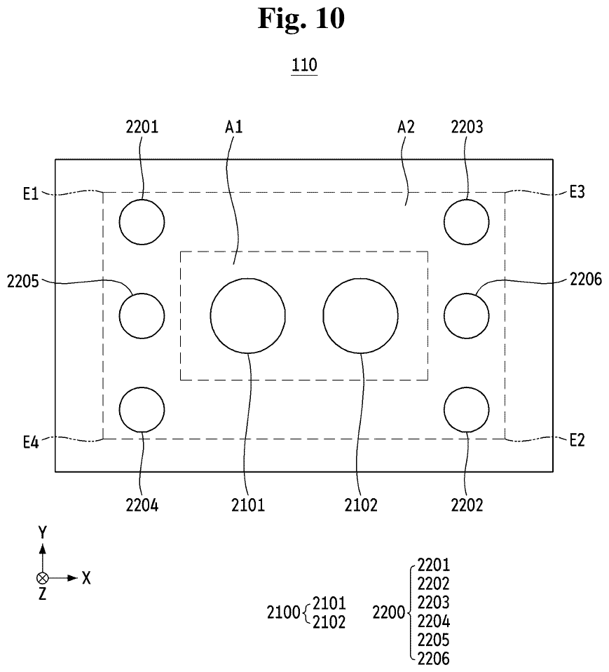

Referring to FIG. 10, an adsorption unit 110 may include a first region A1 and a second region A2. The first region A1 may be disposed at or about the center of the adsorption unit 110. The second region A2 may be disposed about the second region A2 and may surround the second region A2 along the outer edge of the second region A2.

In some example embodiments, the first region A1 may include a plurality of first suction holes 2100. The first suction holes 2100 may be arranged along a first direction X. For example, the first suction holes 2100 may include a first sub-suction hole 2101 and a second sub-suction hole 2102. The first suction holes 2100 are illustrated as including two sub-suction holes, but example embodiments are not limited thereto. Alternatively, the first suction holes 2100 may include three or more sub-suction holes.

In some example embodiments, the second region A2 may include a plurality of second suction holes 2200. The second suction holes 2200 may be arranged along the corners of the second region A2. For example, the second region A2 may include a first corner E1 and a second corner E2 diagonally opposite to each other, and a third corner E3 and a fourth corner E4 diagonally opposite to each other. The third sub-suction hole 2201 may be disposed at the first corner E1. The fourth sub-suction hole 2202 may be disposed at the second corner E2. The fifth sub-suction hole 2203 may be disposed at the third corner E3. The sixth sub-suction hole 2204 may be disposed at the fourth corner E4.

Additionally, the second suction holes 2200 may further include the eleventh sub-suction hole 2205 between the third and sixth sub-suction holes 2201 and 2204, and the twelfth sub-suction hole 2206 between the fourth and fifth sub-suction holes 2202 and 2203.

By disposing the second suction holes 2200 along the corners and both sides of the second region A2, a semiconductor chip 300 can be securely adsorbed.

In some example embodiments, the size of the first suction holes 2100 may be larger than the size of the second suction holes 2200. The area of the first suction holes 2100 may be between 60% (or about 60%) and 80% (or about 80%) of the sum of the areas of the first suction holes 2100 and the second suction holes 2200 included in the adsorption unit 110. In some example embodiments, the area of the first suction holes 2100 may be 60% (or about 60%) of the total area of the suction holes 2100 and 2200.

Additionally, the area of the first region A1 may be less than 30% (or about 30%) of the total area of the adsorption unit 110.

By adjusting the area of the suction holes (2100 and 2200) and the area of the regions (A1 and A2) where the suction holes (2100 and 2200) are disposed, an appropriate (or desired) pressure for adsorbing the semiconductor chip 300 may be generated in each of the regions (A1 and A2). As a result, a single collet apparatus 1 may adsorb semiconductor chips 300 of different (or varied) sizes. The collet apparatus 1 may have improved compatibility.

The adsorption unit 110 may include a material having a relatively higher resistance and/or higher hardness properties. For example, the adsorption unit 110 may include ceramic, but example embodiments are not limited thereto. Alternatively, in some example embodiments, the adsorption unit 110 may include a material with higher resistance and/or higher hardness properties than ceramic. As a result, the collet apparatus 1 may have improved durability.

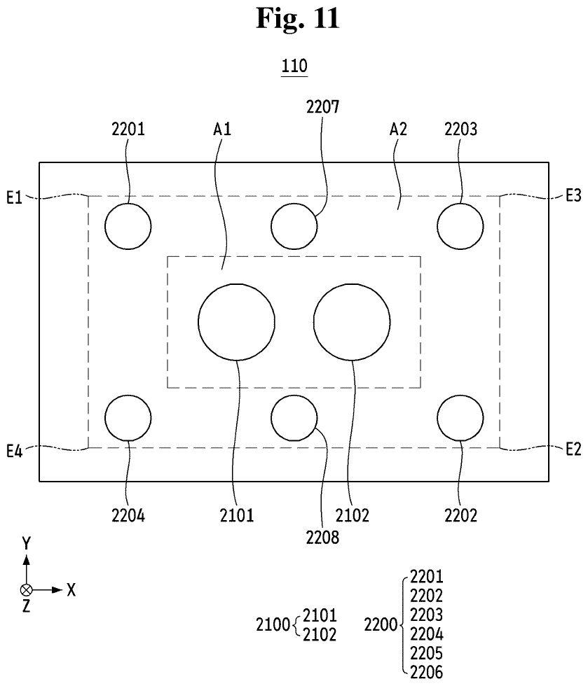

Referring to FIG. 11, an adsorption unit 110 may include a first region A1 and a second region A2. The first region A1 may be disposed at or about the center of the adsorption unit 110. The second region A2 may be disposed about the first region A1 and may surround the first region A1 along the outer edge of the first region A1.

In some example embodiments, the first region A1 may include a plurality of first suction holes 2100. The first suction holes 2100 may be arranged along a first direction X. For example, the first suction holes 2100 may include a first sub-suction hole 2101 and a second sub-suction hole 2102. The first suction holes 2100 are illustrated as including two sub-suction holes, but example embodiments are not limited thereto. Alternatively, the first suction holes 2100 may include three or more sub-suction holes.

In some example embodiments, the second region A2 may include a plurality of second suction holes 2200. The second suction holes 2200 may be arranged along the corners of the second region A2. For example, the second region A2 may include a first corner E1 and a second corner E2 diagonally opposite to each other, and a third corner E3 and a fourth corner E4 diagonally opposite to each other. The third sub-suction hole 2201 may be disposed at the first corner E1. The fourth sub-suction hole 2202 may be disposed at the second corner E2. The fifth sub-suction hole 2203 may be disposed at the third corner E3. The sixth sub-suction hole 2204 may be disposed at the fourth corner E4.

Additionally, the second suction holes 2200 may further include the fifteenth sub-suction hole 2207 between the third and fifth sub-suction holes 2201 and 2203, and the sixteenth sub-suction hole 2208 between the fourth and sixth sub-suction holes 2202 and 2204.

By disposing the second suction holes 2200 and third suction holes 2300 along the corners and both sides of the second region A2 and the third region A3, respectively, a semiconductor chip 300 may be securely adsorbed.

In some example embodiments, the size of the first suction holes 2100 may be larger than the size of the second suction holes 2200. The area of the first suction holes 2100 may be between 60% (or about 60%) and 80% (or about 80%) of the sum of the areas of the first suction holes 2100 and the second suction holes 2200 included in the adsorption unit 110. In some example embodiments, the area of the first suction holes 2100 may be 60% (or about 60%) of the total area of the suction holes 2100 and 2200.

Additionally, the area of the first region A1 may be less than 30% (or about 30%) of the total area of the adsorption unit 110.

By adjusting the area of the suction holes (2100 and 2200) and the area of the regions (A1 and A2) where the suction holes (2100 and 2200) are disposed, an appropriate (or desired) pressure for adsorbing the semiconductor chip 300 may be generated in each of the regions (A1 and A2). As a result, a single collet apparatus 1 may adsorb semiconductor chips 300 of different (or varied) sizes. The collet apparatus 1 may have improved compatibility.

The adsorption unit 110 may include a material having a relatively higher resistance and/or higher hardness properties. For example, the adsorption unit 110 may include ceramic, but example embodiments are not limited thereto. Alternatively, in some example embodiments, the adsorption unit 110 may include a material having a higher resistance and/or higher hardness properties than ceramic. As a result, the collet apparatus 1 may have improved durability.

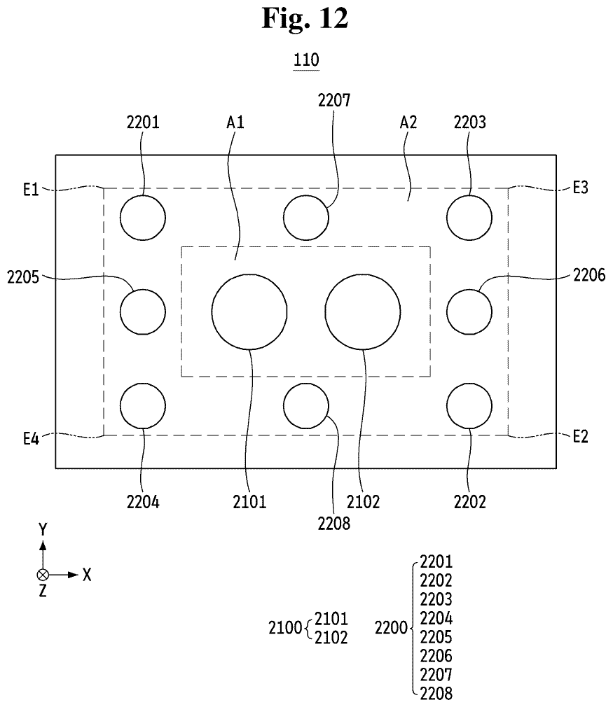

Referring to FIG. 12, an adsorption unit 110 may include a first region A1 and a second region A2. The first region A1 may be disposed at or about the center of the adsorption unit 110. The second region A2 may be disposed about the first region A1 and may surround the first region A1 along the outer edge of the first region A1.

In some example embodiments, the first region A1 may include a plurality of first suction holes 2100. The first suction holes 2100 may be arranged along a first direction X. For example, the first suction holes 2100 may include a first sub-suction hole 2101 and a second sub-suction hole 2102. The first suction holes 2100 are illustrated as including two sub-suction holes, but example embodiments are not limited thereto. Alternatively, the first suction holes 2100 may include three or more sub-suction holes.

In some example embodiments, the second region A2 may include a plurality of second suction holes 2200. The second suction holes 2200 may be arranged along the corners of the second region A2. For example, the second region A2 may include a first corner E1 and a second corner E2 diagonally opposite to each other, and a third corner E3 and a fourth corner E4 diagonally opposite to each other. The third sub-suction hole 2201 may be disposed at the first corner E1. The fourth sub-suction hole 2202 may be disposed at the second corner E2. The fifth sub-suction hole 2203 may be disposed at the third corner E3. The sixth sub-suction hole 2204 may be disposed at the fourth corner E4.

Additionally, the second suction holes 2200 may further include the eleventh sub-suction hole 2205 between the third and sixth sub-suction holes 2201 and 2204, the twelfth sub-suction hole 2206 between the fourth and fifth sub-suction holes 2202 and 2203, the fifteenth sub-suction hole 2207 between the third and fifth sub-suction holes 2201 and 2203, and the sixteenth sub-suction hole 2208 between the fourth and sixth sub-suction holes 2202 and 2204.

By disposing the second suction holes 2200 along the corners and the four sides of the second region A2, a semiconductor chip 300 may be securely adsorbed.

In some example embodiments, the size of the first suction holes 2100 may be larger than the size of the second suction holes 2200. The area of the first suction holes 2100 may be between 60% (or about 60%) and 80% (or about 80%) of the sum of the areas of the first suction holes 2100 and the second suction holes 2200 included in the adsorption unit 110. In some example embodiments, the area of the first suction holes 2100 may be 60% (or about 60%) of the total area of the suction holes (2100 and 2200).

Additionally, the area of the first region A1 may be less than 30% (or about 30%) of the total area of the adsorption unit 110.

By adjusting the area of the suction holes (2100 and 2200) and the area of the regions (A1 and A2) where the suction holes (2100 and 2200) are disposed, an appropriate (or desired) pressure for adsorbing the semiconductor chip 300 may be generated in each of the regions (A1 and A2). As a result, the single collet apparatus 1 may adsorb semiconductor chips 300 of different (or varied) sizes. The collet apparatus 1 may have improved compatibility.

The adsorption unit 110 may include a material having a relatively higher resistance and/or higher hardness properties. For example, the adsorption unit 110 may include ceramic, but example embodiments are not limited thereto. Alternatively, in some example embodiments, the adsorption unit 110 may include a material having a higher resistance and/or higher hardness properties than ceramic. As a result, a collet apparatus 1 may have improved durability.

While several example embodiments have been provided in the present disclosure, it should be understood that the disclosed systems might be embodied in many other specific forms without departing from the spirit or scope of the present disclosure. The present examples embodiments are to be considered as illustrative and not restrictive, and the intention is not to be limited to the details given herein. For example, the various elements or components may be combined or integrated in another system or certain features may be omitted, or not implemented.

What is claimed is:

1. A collet apparatus comprising:
a body unit; and
an adsorption unit connected to a lower part of the body unit, the adsorption unit being configured to adsorb a semiconductor chip, wherein
the adsorption unit includes a first region, a second region, and a third region,
the second region surrounds the first region,
the third region surrounds the second region,
the first region includes a plurality of first suction holes,
the second region includes a plurality of second suction holes,
the third region includes a plurality of third suction holes,
a size of each of the plurality of second suction holes is smaller than a size of each of the plurality of first suction holes, and
a size of each of the plurality of third suction holes is smaller than the size of each of the plurality of second suction holes.

2. The collet apparatus of claim 1, wherein
an area of the plurality of first suction holes is at least 60% of a sum of areas of the plurality of first suction holes, the plurality of second suction holes, and the plurality of third suction holes.

3. The collet apparatus of claim 2, wherein the area of the plurality of second suction holes is at least 15% of the sum of areas of the plurality of first suction holes, the plurality of second suction holes, and the plurality of third suction holes.

4. The collet apparatus of claim 1, wherein
the plurality of first suction holes includes a first sub-suction hole and a second sub-suction hole along a first direction,
the plurality of second suction holes includes a third sub-suction hole and a fourth sub-suction hole at a first corner and a second corner, respectively, of the second region, and a fifth sub-suction hole and a sixth sub-suction hole at a third corner and a fourth corner, respectively, of the second region, wherein
the first corner and the second corner are opposite to each other, and
the third corner and the fourth corner being opposite to each other, and
the plurality of third suction holes includes a seventh sub-suction hole and an eighth sub-suction hole at a fifth corner and a sixth corner, respectively, of the third region, and a ninth sub-suction hole and a tenth sub-suction hole at a seventh corner and an eighth corner, respectively, of the third region, wherein
the fifth corner and the sixth corner are opposite to each other, and
the seventh corner and the eighth corner are opposite to each other.

5. The collet apparatus of claim 4, wherein
the plurality of second suction holes further includes an eleventh sub-suction hole between the third and fifth sub-suction holes, and a twelfth sub-suction hole between the fourth and sixth sub-suction holes, and
the plurality of third suction holes further includes a thirteenth sub-suction hole between the seventh and ninth sub-suction holes, and a fourteenth sub-suction hole between the eighth and tenth sub-suction holes.

6. The collet apparatus of claim 5, wherein
the plurality of second suction holes further includes a fifteenth sub-suction hole between the third and sixth sub-suction holes, and a sixteenth sub-suction hole between the fourth and fifth sub-suction holes, and
the plurality of third suction holes further includes a seventeenth sub-suction hole between the seventh and tenth sub-suction holes, and an eighteenth sub-suction hole between the eighth and ninth sub-suction holes.

7. The collet apparatus of claim 4, wherein
the plurality of second suction holes further includes an eleventh sub-suction hole between the third and sixth sub-suction holes, and a twelfth sub-suction hole between the fourth and fifth sub-suction holes, and
the plurality of third suction holes further includes a thirteenth sub-suction hole between the seventh and tenth sub-suction holes, and a fourteenth sub-suction hole between the eighth and ninth sub-suction holes.

8. The collet apparatus of claim 1, wherein
an area of the first region is less than 30% of a total area of the adsorption unit, and
a sum of the area of the first region and an area of the second region is less than 60% of the total area of the adsorption unit.

9. The collet apparatus of claim 1, wherein the adsorption unit includes ceramic.

10. The collet apparatus of claim 1, further comprising:
a suction line connected to the plurality of first suction holes, the plurality of second suction holes, and the plurality of third suction holes,
wherein the suction line is configured to adsorb the semiconductor chip.

11. A collet apparatus comprising:
a body unit; and
an adsorption unit connected to a lower part of the body unit, the adsorption unit being configured to adsorb a semiconductor chip, wherein
the adsorption unit includes a first region and a second region,
the second region surrounds the first region,
the first region includes a plurality of first suction holes,
the second region includes a plurality of second suction holes, and
a size of each of the plurality of second suction holes is smaller than a size of each of the plurality of first suction holes.

12. The collet apparatus of claim 11, wherein
an area of the plurality of first suction holes is at least 60% of a sum of areas of the plurality of first suction holes and the plurality of second suction holes.

13. The collet apparatus of claim 11, wherein
the plurality of first suction holes include a first sub-suction hole and a second sub-suction hole along a first direction, and
the plurality of second suction holes include a third sub-suction hole and a fourth sub-suction hole at a first corner and a second corner, respectively, of the second region, and a fifth sub-suction hole and a sixth sub-suction hole at a third corner and a fourth corner, respectively, of the second region, wherein
the first corner and the second corner are opposite to each other, and
the third corner and the fourth corner are opposite to each other.

14. The collet apparatus of claim 13, wherein the plurality of second suction holes further includes a seventh sub-suction hole between the third and fifth sub-suction holes, and an eighth sub-suction hole between the fourth and sixth sub-suction holes.

15. The collet apparatus of claim 14, wherein the plurality of second suction holes further includes a ninth sub-suction hole between the third and sixth sub-suction holes, and a tenth sub-suction hole between the fourth and fifth sub-suction holes.

16. The collet apparatus of claim 13, wherein the plurality of second suction holes further includes a seventh sub-suction hole between the third and sixth sub-suction holes, and an eighth sub-suction hole between the fourth and fifth sub-suction holes.

17. The collet apparatus of claim 11, wherein an area of the first region is less than 30% of a total area of the adsorption unit.

18. The collet apparatus of claim 11, further comprising:
a suction line connected to the plurality of first suction holes and the plurality of second suction holes, the suction line being configured to adsorb the semiconductor chip.

19. A collet apparatus comprising:
a body unit;
an adsorption unit connected to a lower part of the body unit, the adsorption unit being configured to adsorb a semiconductor chip; and
a suction line configured to adsorb the semiconductor chip to the adsorption unit, wherein
the adsorption unit includes a first region, a second region, and a third region,
the second region surrounds the first region,
the third region surrounds the second region,
the first region includes a plurality of first suction holes,
the second region includes a plurality of second suction holes,
the third region includes a plurality of third suction holes,
a size of each of the plurality of second suction holes is smaller than a size of each of the plurality of first suction holes,
a size of each of the plurality of third suction holes is smaller than the size of each of the plurality of second suction holes,
an area of the plurality of first suction holes is at least 60% of a sum of areas of the plurality of first suction holes, the plurality of second suction holes, and the plurality of third suction holes,
an area of the first region is less than 30% of a total area of the adsorption unit, and
the suction line is connected to the plurality of first suction holes, the plurality of second suction holes, and the plurality of third suction holes.

20. The collet apparatus of claim 19, wherein
the plurality of first suction holes includes a first sub-suction hole and a second sub-suction hole along a first direction,
the plurality of second suction holes includes a third sub-suction hole and a fourth sub-suction hole at a first corner and a second corner, respectively, of the second region, and a fifth sub-suction hole and a sixth sub-suction hole at a third corner and a fourth corner, respectively, of the second region, wherein
the first corner and the second corner are opposite to each other, and
the third corner and the fourth corner are opposite to each other, and
the plurality of third suction holes includes a seventh sub-suction hole and an eighth sub-suction hole at a fifth corner and a sixth corner, respectively, of the third region, and a ninth sub-suction hole and a tenth sub-suction hole at a seventh corner and an eighth corner, respectively, of the third region, wherein
the fifth corner and the sixth corner are opposite to each other, and
the seventh corner and the eighth corner are opposite to each other.
